(19) United States
(12) Patent Application Publication
(10) Pub. No.: US 2014/0007425 A1
(43) Pub. Date: Jan. 9, 2014

(54) MANUFACTURING METHOD OF ELECTRONIC PACKAGING

(71) Applicants: Ju-Mei LU, Taichung City (TW); Yao-Min Huang, Taichung City (TW); Jui-Chin Peng, Taichung City (TW); Shih-Ting Yang, Taichung City (TW); Chao-Ching Huang, Taichung City (TW)

(72) Inventors: Ju-Mei LU, Taichung City (TW); Yao-Min Huang, Taichung City (TW); Jui-Chin Peng, Taichung City (TW); Shih-Ting Yang, Taichung City (TW); Chao-Ching Huang, Taichung City (TW)

(73) Assignee: MERRY ELECTRONICS CO., LD, TAICHUNG CITY (TW)

(21) Appl. No.: 13/542,178

(22) Filed: Jul. 5, 2012

(51) Int. Cl. H05K 3/22

(52) U.S. Cl. 29/831

(57) ABSTRACT

A manufacturing method of electronic packaging includes the steps of preparing a metallic plate having an array of cover portions, soldering the metallic plate to a circuit board having encapsulated areas corresponding to the cover portions and employing a cutting process to obtain multiple electronic packages. Thus, the invention has the advantages of low cost and high efficiency

### BACKGROUND OF THE INVENTION

1. Field of the Invention

The present invention relates to the fabrication of electronic packages and more particularly, to a manufacturing method of electronic packaging for fabricating electronic packages rapidly.

2. Description of the Related Art

Conventionally, the fabrication of electronic packages, for example, MEMS (MicroElectrical-Mechanical System) microphone packages, is to form a plurality of encapsulated areas with electronic devices on a circuit board, and then to stack metallic covers on the encapsulated areas of the circuit board individually by means of a pick-and-place machine, and then to perform reflowing and cutting processes, thereby obtaining the desired electronic packages.

This conventional electronic package manufacturing method is complicated and time-consuming. Further, if the size of the electronic package is reduced, this method may be unable to accurately position the metal covers on the encapsulated areas, lowering the yield rate and increasing the manufacturing cost.

### SUMMARY OF THE INVENTION

The present invention has been accomplished under the circumstances in view. It is the main object of the present invention to provide a manufacturing method of electronic packaging, which effectively shortens electronic package manufacturing time, reduces electronic package manufacturing cost and simplifies electronic package manufacturing process.

To achieve this and other objects of the present invention, a manufacturing method of electronic packaging comprises the steps of: (a) preparing a metallic plate comprising a plurality of cover portions arranged in an array and a bridge portion connecting the cover portions; (b) soldering the metallic plate to a circuit board comprising a plurality of encapsulated areas corresponding to the cover portions to enable the encapsulated areas to be covered by the cover portions; and (c) cutting the metallic plate and the circuit board along the bridging portion to obtain a plurality of electronic packages. By means of directly stacking a metallic cover array-like metallic plate having an array of cover portions on a printed circuit board having multiple encapsulating areas, the invention enables multiple cover portions to be accurately positioned on a printed circuit board, effectively shortening the electronic package manufacturing time, reducing the electronic package manufacturing cost and simplifying the electronic package manufacturing process.

Further, the step (b) is achieved by means of applying a solder material to at least one of the metallic plate and the circuit board and then employing a reflow soldering technique to solder the metallic plate to the circuit board.

Further, the step (a) for preparing the metallic plate having a sound hole on each cover portion for the passing of sound waves comprises the sub-steps of: (a1) forming a release layer on a substrate and an array of insulative blocks on said release layer; (a2) forming a seed layer on the release layer and the insulative blocks, the seed layer comprising a plurality of protrusions corresponding to said insulative blocks for forming the cover portion and a plurality of connection portions connected with the protrusions for forming the bridge portion, and then forming a plurality of insulative blocks on the protrusions of said seed layer for forming the sound hole on each said cover portion; (a3) electroplating a metallic layer on the seed layer for forming the metallic plate; and (a4) removing the substrate, the release layer, said insulative blocks and the seed layer in proper order so to obtain the metallic plate.

It is to be understood that the metallic plate can be prepared without any sound hole on the cover portion. In this case, the sound hole forming step in the sub-step (a2) is omitted.

Further, in step (a), the metallic plate can be prepared having a sound hole on each cover portion, and a plurality of through holes on the bridge portion. In this case, after the formation of the seed layer on the release layer and the insulative blocks, it simply needs to form insulative blocks on the protrusions of the seed layer for forming the sound holes, and to form insulative blocks on the connection portions of the seed layer. Thereafter, perform the metallic layer plating process, and then remove the substrate, the insulative blocks and the seed layer.

The preparation of the metallic plate having multiple through holes on the bridge portion thereof reduces the material consumption and stress-induced deformation, facilitating the follow-up cutting process.

Based on the spirit of the present invention, during the preparation of the metallic plate, the seed layer can be made having the protrusions and the connection portions by means of: forming on the substrate a release layer having an array of protrusions and connection portions that connect the protrusions and then forming the seed layer on the release layer, or alternatively, forming a release layer on a substrate having an array of protrusions and connection portions connecting the protrusions and then forming the seed layer on the release layer.

Further, the substrate can be selected from the group of silicon substrate, metallic substrate, glass substrate and plastic substrate; the release layer can be selected from the group of thermal tape, UV tape, photoresist, metal material and dielectric material; the seed layer can be selected from the group of chromium/copper (Cr/Cu), titanium/copper (Ti/Cu) and titanium tungsten/copper (TiW/Cu); the metallic layer can be selected from the group of nickel (Ni), copper (Cu) and nickel-chrome alloy (NiCo); the insulative blocks can be prepared using photoresist.

Further, the metallic plate can be prepared using die-casting or stamping techniques.

Other and further benefits, advantages and features of the present invention will be understood by reference to the following specification in conjunction with the accompanying drawings, in which like reference characters denote like elements of structure.

### BRIEF DESCRIPTION OF THE DRAWINGS

FIG. 1 is a manufacturing flow chart of a manufacturing method of electronic packaging in accordance with the present invention.

FIG. 2 is a schematic drawing illustrating the manufacturing method of electronic packaging of FIG. 1.

FIG. 3 is a manufacturing flow chart of a metallic plate preparation process for the manufacturing method of electronic packaging in accordance with the present invention, wherein each cover portion of the metallic plate provides a sound hole.

FIG. 4 is a manufacturing flow chart of an alternate form of the metallic plate preparation process for the manufacturing method of electronic packaging in accordance with the present invention, wherein the metallic plate provides cover portions without any sound hole.

FIGS. 5-10 are schematic drawings, illustrating the preparation of the metallic plate shown in FIG. 2.

FIG. 11 is similar to FIG. 6 but illustrating the relative positioning between the insulative blocks formed on the seed layer and the insulative blocks for the cover portions.

FIGS. 12A and 12B are schematic drawings illustrating multiple through holes formed in the bridge portion of the metallic plate.

FIG. 13 is similar to FIG. 5 but illustrating the configuration of the protrusion array on the release layer.

FIG. 14 is similar to FIG. 5 but illustrating the configuration of the protrusion array on the substrate.

### DETAILED DESCRIPTION OF THE INVENTION

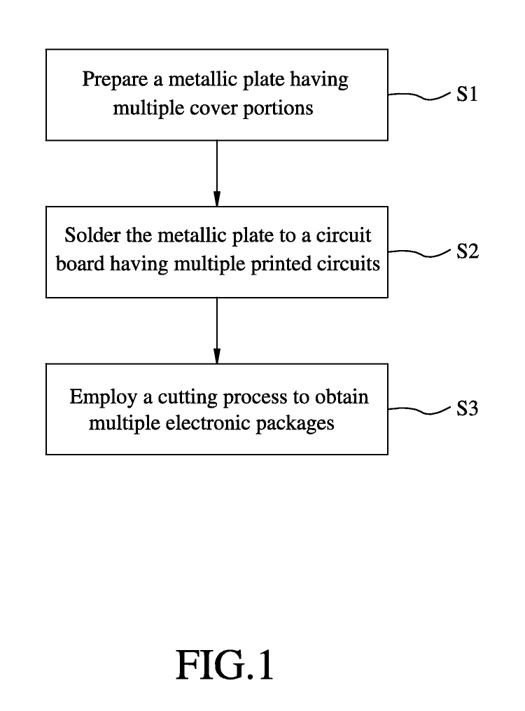

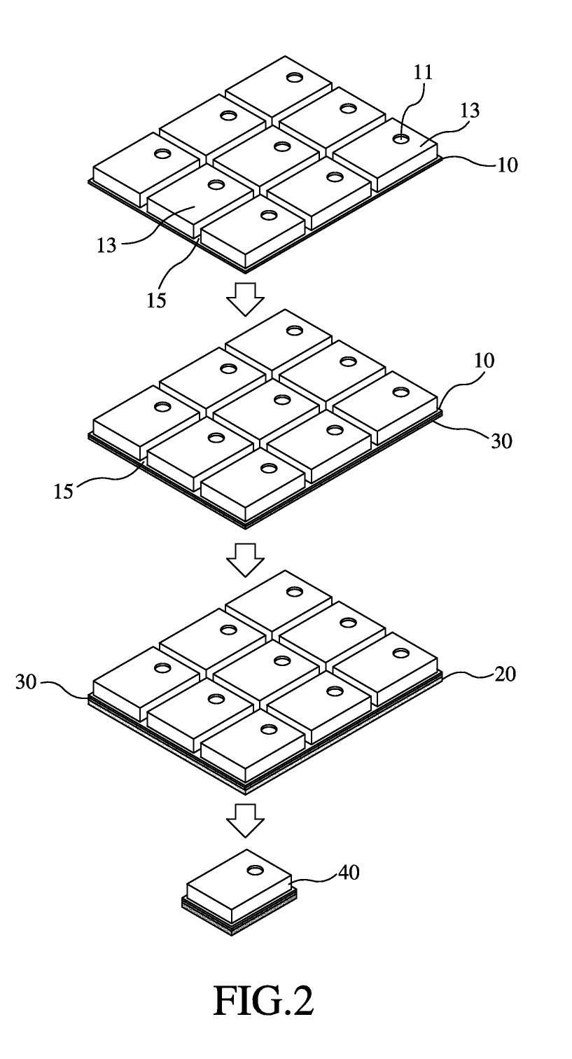

Referring to FIGS. 1 and 2, a manufacturing method in accordance with the invention is adapted for manufacturing, for example, but not limited to, MEMS (MicroElectrical-Mechanical System) microphone packages. This manufacturing method includes the following steps:

At first, in step S1, prepare a metallic plate 10, which comprises a plurality of cover portions 13 arranged in an array, each cover portion having a sound hole 11 for the passing of sound waves, and a bridge portion 15 connecting the cover portions 13. There are no special restrictions on the material of the metallic plate 10. Materials commonly seen in electronic packaging can be selectively used.

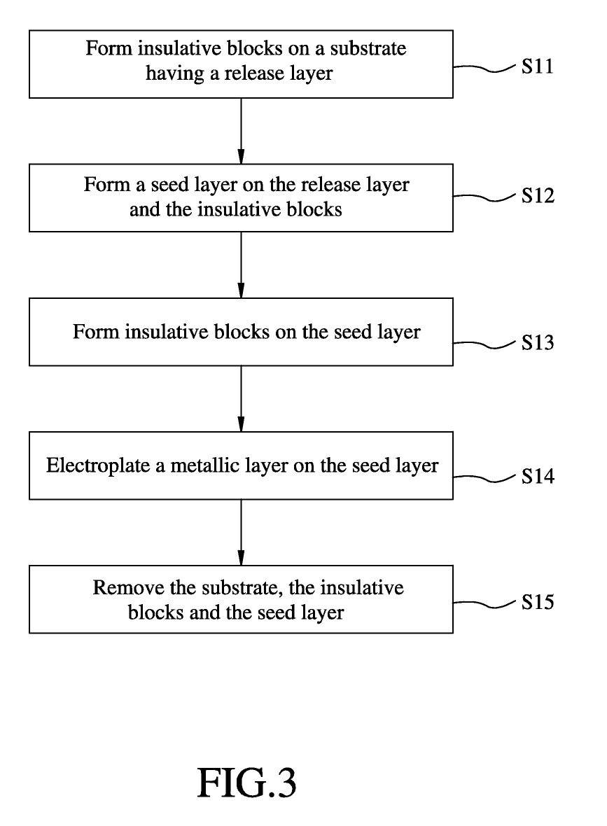

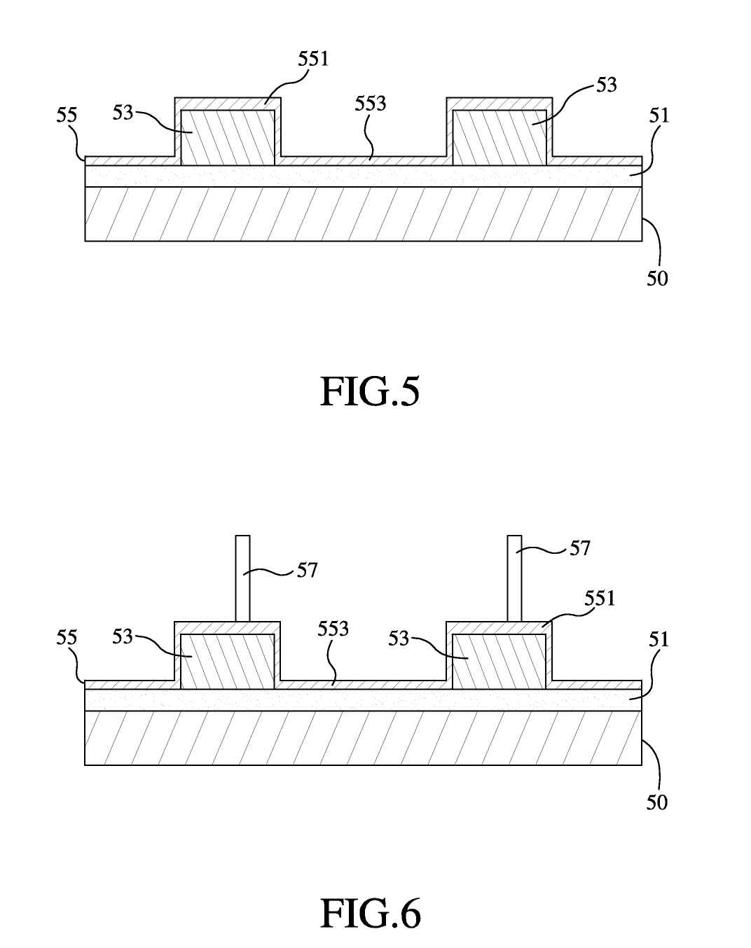

According to this embodiment, the metallic plate 10 is prepared by using the method illustrated in FIG. 3 and FIGS. 5-10. Detailedly speaking, the preparation of the metallic plate 10 includes sub-steps of S11-15, as shown in FIG. 3. During sub-step S11, as shown in FIG. 5, forming a release layer 51 on the surface of a substrate 50, and then forming an array of spaced insulative blocks 53 on the release layer 51. The substrate 50 can be a silicon substrate, metallic substrate, glass substrate or plastic substrate. Preferably, the substrate 50 is a silicon substrate. The release layer 51 can be selected from the group of thermal tape, UV tape, photoresist, metal material and dielectric material. The insulative blocks 53 are preferably prepared using photoresist.

Thereafter, proceed to sub-step S12. During sub-step S12, as illustrated in FIG. 5, form a seed layer 55 on the release layer 51 and the insulative blocks 53, enabling the seed layer 55 to provide a plurality of protrusions 551 corresponding to the insulative blocks 53 for forming the said cover portions 13 and a plurality of connection portions 553 connected with the protrusions 551 for forming the said bridge portion 15. At this time, the material for the seed layer 55 is preferably selected from the group of chromium/copper (Cr/Cu), titanium/copper (Ti/Cu) and titanium tungsten/copper (TiW/Cu).

Thereafter, proceed to sub-step S13. During sub-step S13, as illustrated in FIG. 6, form a plurality of insulative blocks 57 on the protrusions 551 of the seed layer 55 for forming the said sound holes 11. At this time, these insulative blocks 57 are preferably prepared using photoresist, and the size of these insulative blocks 57 must be relatively smaller than the size of the aforesaid insulative blocks 53.

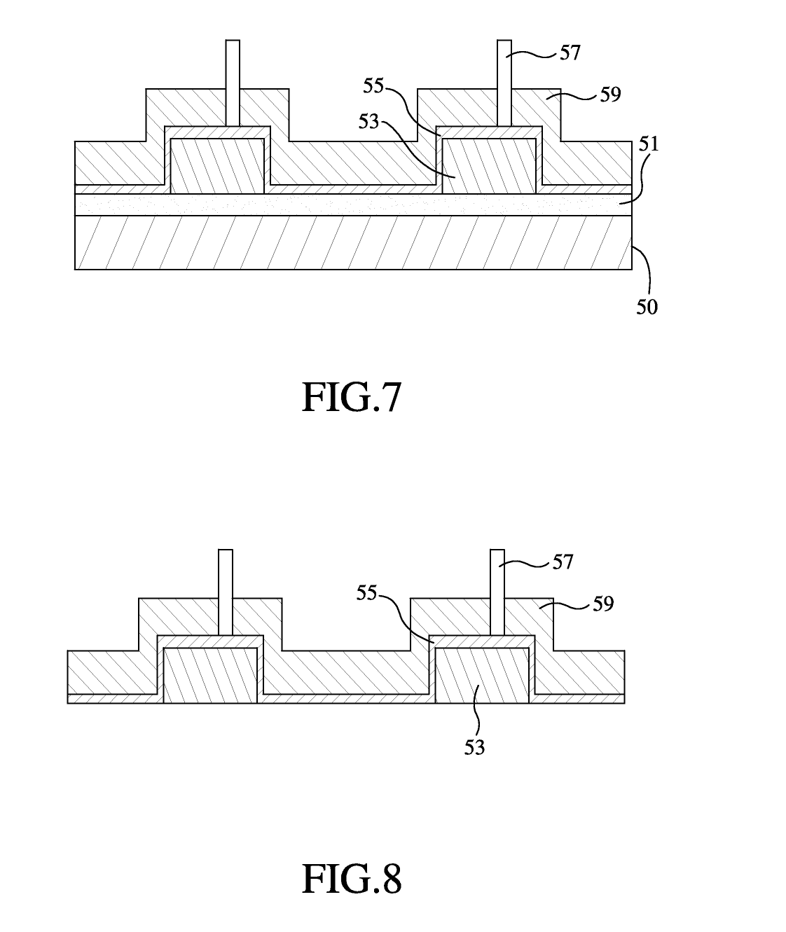

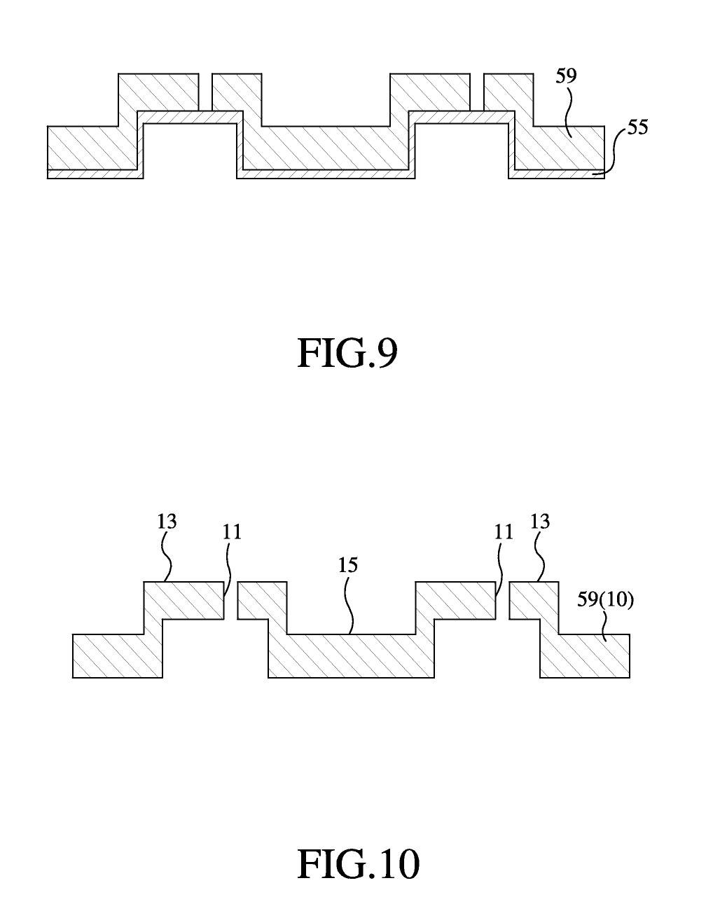

Thereafter, proceed to sub-step S14. During sub-step S14, as illustrated in FIG. 7, electroplate a metallic layer 59 on the seed layer 55 for forming the aforesaid metallic plate 10, leaving the insulative blocks 57 exposed to the outside. At this time, the metallic layer 59 is preferably selected from the group of nickel (Ni), copper (Cu) and nickel-chrome alloy (NiCo). Thereafter, proceed to the last sub-step S15, during this last sub-step S15, remove the substrate 50 and the release layer 51 (see FIG. 8), and then remove the insulative blocks 53 [symbol] 57 (see FIG. 9), and then remove the seed layer 55 (see FIG. 10), thereby obtaining the desired metallic plate 10, which comprises an array of cover portions 13 each cover portion provided with a sound hole 11, and a bridge portion 15 connecting the cover portions 13. There are no special restrictions on removing the insulative 53;57 and the seed layer 55. Removing the insulative 53 [symbol] 57 and the seed layer 55 can be achieved using conventional techniques, for example, using a stripper to remove the insulative 53;57 and employing an etching technique to remove the seed layer 55.

After preparation of the metallic plate 10, proceed to step S2. During step S2, as shown in FIGS. 1 and 2, solder the metallic plate 10 to a circuit board 20 having a plurality of encapsulated areas (not shown) corresponding to the cover portions 13, enabling the cover portions 13 to cover the respective encapsulated areas. During this step, the metallic plate 10 is soldered to a circuit board 20 by means of (but not limited to) applying a solder 30, for example, tin paste to the metallic plate 10 and then employing a reflow soldering technique. In actual practice, the solder material 30 can also be applied to the circuit board 20.

At final, proceed to step S3. During step S3, cut the metallic plate 10 and the circuit board 20 along the bridge portion 15, thereby obtaining multiple electronic packages 40.

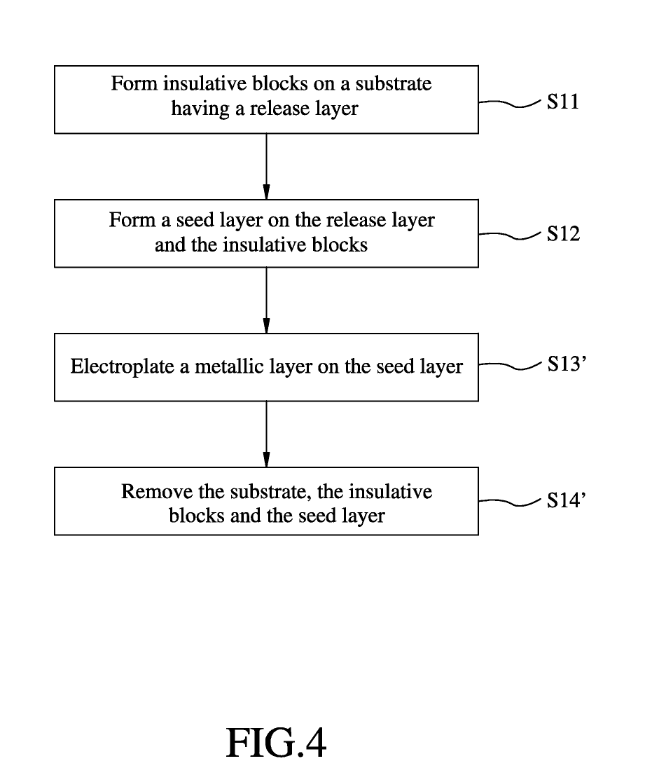

Because the aforesaid embodiment is an example of the present invention for manufacturing MEMS (MicroElectrical-Mechanical System) microphone packages, each cover portion 13 of the metallic plate 10 must provide a sound hole 11 for the passing of sound waves. However, in actual application, the metallic plate 10 can be prepared without the aforesaid sound holes 11. Detailedly speaking, the preparation of the metallic plate 10 can be alternatively achieved subject to the manufacturing flow chart shown in FIG. 4. After formation of the structure shown in FIG. 5 subject to the sub-steps of S11 and S12, proceed to sub-step S13′ to electroplate a metallic layer 59 on the seed layer 55, and then proceed to sub-step 14′ to remove the substrate 50 and release layer 51, the insulative blocks 53 and the seed layer 55, thereby obtaining the desired metallic plate 10.

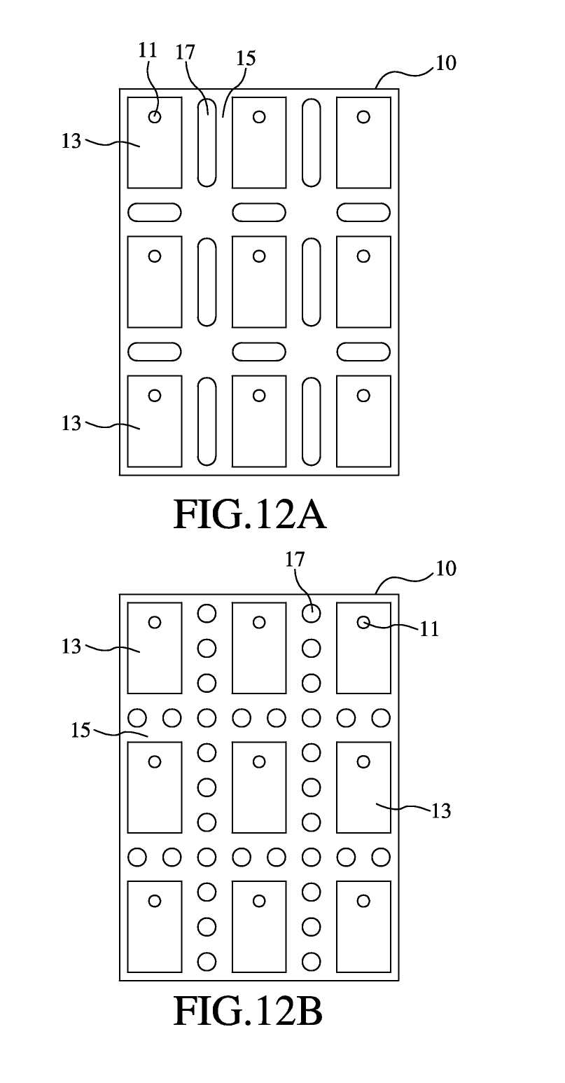

It is to be noted that the configuration of the metallic plate 10 used in the manufacturing method of the present invention is not limited to the aforesaid example. In other alternate forms shown in FIGS. 12A and 12B, the metallic plate 10 further comprises a plurality of through holes 17 located on the bridge portion 15 to reduce material consumption for the metallic layer 59 for forming the metallic plate 10 and the stress-induced deformation in soldering the metallic plate 10 to the circuit board 20, facilitating the follow-up cutting process.

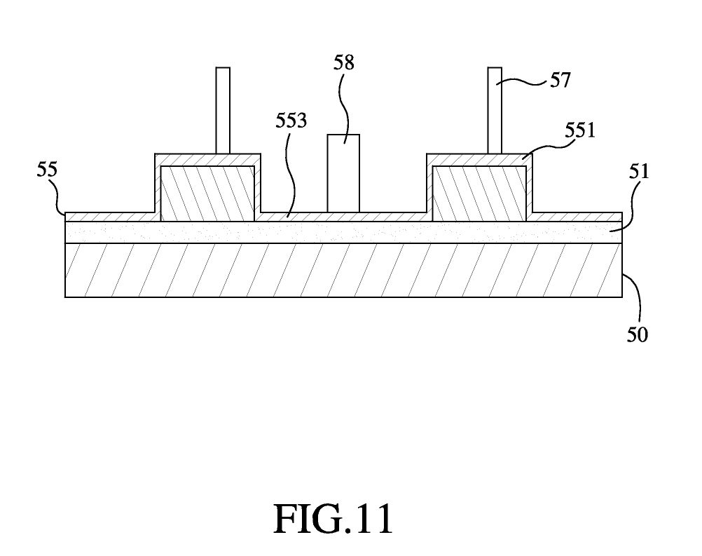

In more detail, perform sub-steps S11-S13 to form the structure shown in FIG. 6, and then, as shown in FIG. 11, form insulative blocks 58 on the connection portions 553 of the seed layer 55 for forming the through holes 17 (only on insulative block is shown in the drawing), and then electroplate the metallic layer 59 on the seed layer 55 for forming the aforesaid metallic plate 10, leaving the insulative blocks 57;58 exposed to the outside, and then remove the substrate 50, the release layer 51, the insulative blocks 53;57;58 and the seed layer 55, thereby obtaining the desired metallic plate 10, as shown in FIGS. 12A and 12B. Further, the through holes 17 can be, but not limited to, circular or oblong through holes configured subject to the configuration of the insulative blocks 58.

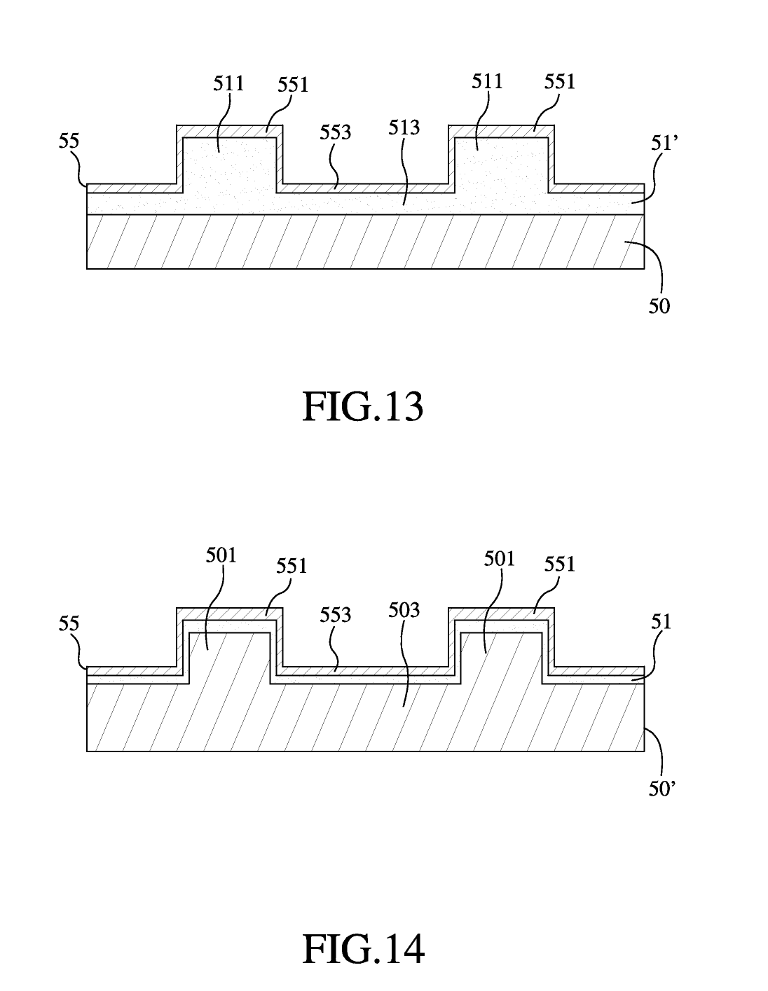

Further, during the preparation of the metallic plate 10, the seed layer 55 can be made to provide the protrusions 551 and the connection portions 553 subject to the following procedures. In more detail, as shown in FIG. 13, the release layer 51′ that is formed on the substrate 50 comprises a plurality of protrusions 511 arranged in an array and a plurality of connection portions 513 connecting the protrusions 511. After formation of the release layer 51′on the substrate 50, form the seed layer 55 on the release layer 51′, wherein the seed layer 55 comprises a plurality of protrusions 551 corresponding to the protrusions 511 of the release layer 51′, and a plurality of connection portions 553 corresponding to the connection portions 513 of the release layer 51′. Alternatively, as shown in FIG. 14, use a substrate 50′ comprising an array of protrusions 501 and a plurality of connection portions 503 connecting the protrusions 501, and then form the seed layer 55 on the release layer 51, wherein the seed layer 55 comprises a plurality of protrusions 551 corresponding to the protrusions 511 of the release layer 51, and a plurality of connection portions 553 corresponding to the connection portions 513 of the release layer 51.

It is to be noted that the preparation of the metallic plate 10 is not limited to the aforesaid methods; die-casting or stamping techniques may be employed to make the metallic plate 10.

In conclusion, the invention is to directly stack a metallic cover array-like metallic plate 10 having an array of cover portions 13 on a printed circuit board having multiple encapsulating areas. When compared to conventional techniques, the invention enables multiple cover portions to be accurately positioned on a printed circuit board, effectively shortening the manufacturing time, reducing the manufacturing cost and simplifying the manufacturing process.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A manufacturing method of electronic packaging, comprising the steps of:
(a) preparing a metallic plate comprising a plurality of cover portions arranged in an array and a bridge portion connecting said cover portions;
(b) soldering said metallic plate to a circuit board comprising a plurality of encapsulated areas corresponding to said cover portions to enable said encapsulated areas to be covered by said cover portions; and
(c) cutting said metallic plate and said circuit board along said bridging portion to obtain a plurality of electronic packages.

2. The manufacturing method of electronic packaging as claimed in claim 1, wherein said step (b) is achieved by means of applying a solder material to at least one of said metallic plate and said circuit board and then employing a reflow soldering technique to solder said metallic plate to said circuit board.

3. The manufacturing method of electronic packaging as claimed in claim 1, wherein said step (a) for preparing said metallic plate comprises the sub-steps of:
(a1) forming a release layer on a substrate;
(a2) forming a seed layer on said release layer, said seed layer comprising a plurality of protrusions arranged in an array for forming said cover portion and a plurality of connection portions connected with said protrusions for forming said bridge portion;
(a3) electroplating a metallic layer on said seed layer for forming said metallic plate; and
(a4) removing said substrate, said release layer and said seed layer in proper order so to obtain said metallic plate.

4. The manufacturing method of electronic packaging as claimed in claim 3, wherein said step (a) of preparing said metallic plate further comprises the sub-step of forming an array of insulative blocks on said release layer after said sub-step (a1) and prior to said sub-step (a2); said sub-step (a2) is to form said seed layer on said release layer and said insulative blocks, enabling said seed layer to provide a plurality of protrusions corresponding to said insulative blocks, and said connection portions; said sub-step (a4) is to remove said substrate, said release layer, said insulative blocks and said seed layer, thereby obtaining said metallic plate.

5. The manufacturing method of electronic packaging as claimed in claim 3, wherein said release layer prepared in said sub-step (a1) comprises a plurality of protrusions arranged in an array and a plurality of connection portions connecting said protrusions so that said seed layer prepared in said sub-step (a2) comprises a plurality of protrusions corresponding to the protrusions of said release layer and a plurality of connection portions corresponding to the connection portions of said release layer.

6. The manufacturing method of electronic packaging as claimed in claim 3, wherein said substrate used in said sub-step (a1) comprises a plurality of protrusions arranged in an array and a plurality of connection portions connecting the protrusions of said substrate so that said seed layer prepared in said sub-step (a2) comprises a plurality of protrusions corresponding to the protrusions of said substrate and a plurality of connection portions corresponding to the connection portions of said substrate.

7. The manufacturing method of electronic packaging as claimed in claim 3, wherein each said cover portion of said metallic plate prepared in said step (a) comprises a sound hole; said step (a) for preparing said metallic plate further comprises, after said sub-step (a2) and prior to said sub-step (a3), the sub-step of forming a plurality of insulative blocks on the protrusions of said seed layer for forming the sound hole on each said cover portion; said sub-step (a4) is to remove said substrate, said release layer, said insulative blocks and said seed layer in proper order, thereby obtaining said metallic plate.

8. The manufacturing method of electronic packaging as claimed in claim 3, wherein said metallic plate prepared in said step (a) comprises a sound hole located on each said cover portion and a plurality of through holes located on said bridge portion; said step (a) for preparing said metallic plate further comprises, after said sub-step (a2) and prior to said sub-step (a3), the sub-step of forming a plurality of insulative blocks on the protrusions of said seed layer for forming the sound hole on each said cover portion; and a plurality of insulative blocks on said connection portions of said seed layer for forming said through holes; said sub-step (a4) is to remove said substrate, said release layer, said insulative blocks and said seed layer in proper order, thereby obtaining said metallic plate.

9. The manufacturing method of electronic packaging as claimed in claims 3, wherein said substrate is selected from the group of silicon substrate, metallic substrate, glass substrate and plastic substrate.

10. The manufacturing method of electronic packaging as claimed in claims 3, wherein said release layer is selected from the group of thermal tape, UV tape, photoresist, metal material and dielectric material.

11. The manufacturing method of electronic packaging as claimed in claims 3, wherein said seed layer is selected from the group of chromium/copper (Cr/Cu), titanium/copper (Ti/Cu) and titanium tungsten/copper (TiW/Cu).

12. The manufacturing method of electronic packaging as claimed in claims 3, wherein said metallic layer is selected from the group of nickel (Ni), copper (Cu) and nickel-chrome alloy (NiCo).

13. The manufacturing method of electronic packaging as claimed in claim 4, wherein said insulative blocks are prepared using photoresist.

14. The manufacturing method of electronic packaging as claimed in claim 7, wherein said insulative blocks are prepared using photoresist.

15. The manufacturing method of electronic packaging as claimed in claim 8, wherein said insulative blocks are prepared using photoresist.

16. The manufacturing method of electronic packaging as claimed in claim 1, wherein said metallic plate is prepared in said step (a) using one of die-casting and stamping techniques.
